(19) United States
(12) Patent Application Publication
(10) Pub. No.: US 2025/0076038 A1
(43) Pub. Date: Mar. 6, 2025

(54) FAST AND ACCURATE STRAIN MAPPING USING ELECTRON DIFFRACTION

(71) Applicant: FEI Company, Hillsboro, OR (US)

(72) Inventors: Stefano Vespucci, Eindhoven (NL); Wouter René J. Van den Broek, Utrecht (NL)

(21) Appl. No.: 18/458,929

(22) Filed: Aug. 30, 2023

(51) Int. Cl. G01B 15/06; H01J 37/244; H01J 37/26; H01J 37/28

(52) U.S. Cl. CPC G01B 15/06; H01J 37/244; H01J 37/265; H01J 37/28; H01J 2237/24475; H01J 2237/24585

(57) ABSTRACT

In some embodiments, a scientific instrument includes an electron-beam column configured to scan an electron beam across a sample and a segmented electron detector configured to receive diffracted beams produced by diffraction of the electron beam in the sample. The segmented electron detector has a plurality of segments arranged in a two-dimensional array, with each of the segments being configured to generate a respective output signal representing a respective integrated flux of electrons received thereat. The scientific instrument also includes an electronic controller configured to receive a set of frames from the segmented electron detector, each of the frames representing a respective set of output signals generated by the segments in response to an electron diffraction pattern projected onto the segmented electron detector, and further configured to communicate with a computing device programmed to generate a strain map of the sample based on the set of frames.

### TECHNICAL FIELD

Various examples relate generally, but not exclusively, to electron microscopy components, instruments, systems, and methods.

### SUMMARY

The microelectronics industry has a need for effective tools to quantitatively measure strain in semiconductor devices. For example, strain in multi-compound semiconductor-based devices can either be unfavorable or advantageous, as strain may affect the incorporation of substituent atoms or provide ways to design electronic devices by strain engineering of the band gap and/or carrier mobility. In general, knowledge of the actual strain state of the specimen is of high importance for quality-control purposes. As such, strain-mapping methods and equipment providing approximately 1 nm spatial resolution and approximately 0.01% to 0.1% strain precision coupled with sufficiently fast data acquisition and processing are of great interest to semiconductor companies.

Disclosed herein are, among other things, various examples, aspects, features, and embodiments of a scientific instrument including an electron-beam column and associated diffraction-pattern acquisition and processing circuitry. The diffraction-pattern acquisition circuitry includes a segmented electron detector having a relatively small total number (e.g., <200) of segments for quantifying the flux of diffracted electrons in a spatially resolved manner. In an example embodiment, the number and shapes of the segments in the segmented electron detector are such that the center-of-mass (COM) coordinates of various pertinent Bragg diffraction spots can be accurately determined based on the output signals of individual segments. An electronic processor connected to the diffraction-pattern acquisition circuitry operates to estimate local strain in the sample based on the determined COM coordinates and further operates to construct a strain map of the sample using the estimated local strain values corresponding to different scan-pixel positions of the electron-beam probe. In some examples, an appropriately shaped diffraction mask overlayed onto the segmented electron detector is used to disambiguate electron fluxes received by some individual segments. In some embodiments, some or all of the above-indicated features can beneficially be leveraged to meet or exceed the above indicated spatial-resolution, strain precision, and/or acquisition-speed targets of semiconductor companies.

One example provides an apparatus comprising: an electron-beam column configured to scan an electron beam across a sample; a segmented electron detector configured to receive a plurality of diffracted beams produced by diffraction of the electron beam in the sample, the segmented electron detector having a plurality of segments arranged in a two-dimensional array, with each of the segments being configured to generate a respective output signal representing a respective integrated flux of electrons received thereat; and an electronic controller configured to receive a set of frames from the segmented electron detector, each of the frames representing a respective set of output signals generated by the segments in response to an electron diffraction pattern projected onto the segmented electron detector from a respective position of the electron beam during a scan of the sample and further configured to communicate with a computing device programmed to generate a strain map of the sample based on the set of frames. In some examples, a total number of segments in the segmented electron detector is smaller than 1000.

Another example provides a strain mapping method comprising: acquiring a set of frames by operating an electron-beam column to scan an electron beam across a sample and further operating a segmented electron detector configured to receive a plurality of diffracted beams produced by diffraction of the electron beam in the sample, the segmented electron detector having a plurality of segments arranged in a two-dimensional array, each of the segments being configured to generate a respective output signal representing a respective integrated flux of electrons received thereby, each of the frames representing a respective set of output signals generated by the segments in response to an electron diffraction pattern projected onto the segmented electron detector from a respective position of the electron beam during a scan of the sample; and generating, with a processor, a strain map of the sample based on the set of frames. In some examples, a total number of segments in the segmented electron detector is smaller than 1000.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a block diagram illustrating an example scientific instrument in accordance with some embodiments.

FIG. 2 is a block diagram illustrating acquisition of a diffraction pattern in the scientific instrument of FIG. 1 in accordance with some embodiments.

FIG. 3 shows a diffraction pattern projected onto an electron detector in the scientific instrument of FIG. 1 according to one example.

FIG. 4 is a block diagram illustrating a layout of a segmented electron detector used in the scientific instrument of FIG. 1 in accordance with one embodiment.

FIG. 5 is a block diagram illustrating a layout of a segmented electron detector used in the scientific instrument of FIG. 1 in accordance with another embodiment.

FIG. 6 is a block diagram illustrating an example diffraction mask that can be used with a segmented electron detector of the scientific instrument of FIG. 1 in accordance with one embodiment.

FIG. 7 is a flowchart illustrating a strain-mapping method that can be implemented in the scientific instrument of FIG. 1 in accordance with some embodiments.

FIG. 8 is a block diagram of an example computing device configured to perform at least some scientific-instrument support operations in accordance with various embodiments.

### DETAILED DESCRIPTION

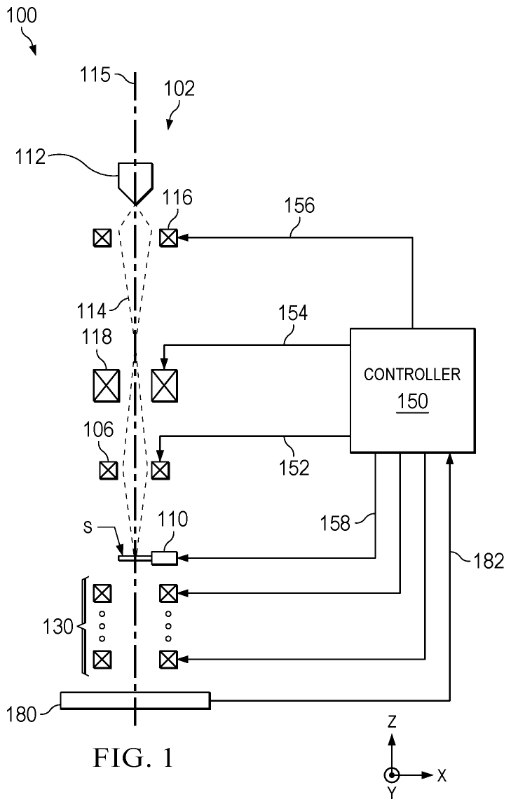

FIG. 1 is a block diagram illustrating a scientific instrument 100 in accordance with some embodiments. The scientific instrument 100 includes a scanning transmission electron microscope (STEM) column 102. In an example embodiment, the sample holder 110 is independently movable parallel to the XY-coordinate plane and parallel to the Z-coordinate axis, with the corresponding coordinate system being indicated by the XYZ-coordinate triad shown in FIG. 1. The sample holder 110 is also rotatable with respect to the XYZ-coordinate frame with or without translation. In some examples, the sample holder 110 includes a goniometer that is independently rotatable at least about eucentric tilt and azimuthal rotation axes that are mutually orthogonal. In other examples, the goniometer may implement rotations about other suitable types of non-parallel rotation axes. A sample S to be interrogated using the scientific instrument 100 is mounted in the sample holder 110 as indicated in FIG. 1. An electronic controller 150 operates to generate a control signal 158, in response to which the sample holder 110 translates and/or rotates the sample S by the specified amounts.

In the example shown, the STEM column 102 comprises an electron source 112 and two or more pre-specimen electron-beam lenses, only two of which, i.e., an objective lens 106 and a condenser lens 116, are schematically shown in FIG. 1 for illustration purposes. In some examples, a different (from two) number of pre-specimen electron-beam lenses may be used in the STEM column 102.

In operation, the electron source 112 generates an electron beam 114 propagating generally along a longitudinal axis 115 of the STEM column 102. Electron-beam lenses 106 and 116 are operated to generate electric and magnetic fields that affect electron trajectories in the electron beam 114. Control signals 152, 156 generated by the electronic controller 150 are used to change the strengths and/or spatial configurations of the fields and impart desired properties on the electron beam 114. In general, the electron-beam lenses 106 and 116, control signals 152 and 156, and other pertinent components of the scientific instrument 100 can be used to perform various operations and support various functions, such as beam focusing, aberration mitigation, aperture cropping, filtering, etc. The STEM column 102 further comprises a deflection unit 118 that can steer the electron beam 114 in response to a control signal 154 applied thereto by the electronic controller 150. Such beam steering can be used to move a focused portion of the electron beam 114 across the sample S.

The STEM column 102 also includes a set 130 of post-specimen electron-beam optics. In an example embodiment, the optics set 130 includes one or more electron-beam lenses and one or more apertures. In operation, the electronic controller 150 generates appropriate control signals to operate the post-specimen electron-beam lenses of the optics set 130 in two or more operating modes, including an imaging mode and a diffraction mode. For strain-mapping applications described herein below, the optics set 130 is typically configured to operate in a diffraction mode.

The scientific instrument 100 also includes one or more detectors, only one of which (labeled 180) is explicitly shown in FIG. 1 for illustration purposes. In operation, the detector 180 generates a stream of measurements 182, which is received by the electronic controller 150. In some examples, the detector 180 is retractable. A specific type of the detector 180 depends on the embodiment and/or operating mode of the scientific instrument 100 and can typically be chosen from a variety of detector types suitable for detecting different types of emission and/or radiation from the sample S produced thereby in response to the electron beam 114. Example types of the emission/radiation that can be produced in this manner include, but are not limited to, X-rays, infrared light, visible light, ultraviolet light, back-scattered electrons, secondary electrons, Auger electrons, elastically scattered electrons, non-scattered (e.g., zero energy loss) electrons, and non-elastically scattered electrons. In some embodiments, the detector 180 is selected from the group consisting of a high-angle annular dark field detector, a medium-angle annular dark field detector, an annular bright field detector, a segmented annular detector, a differential phase contrast detector, and a two-dimensional (e.g., pixelated or segmented) diffraction-pattern detector. Other detectors capable of detecting various ones of the above-mentioned types of emission/radiation can also be used in various additional embodiments of the scientific instrument 100.

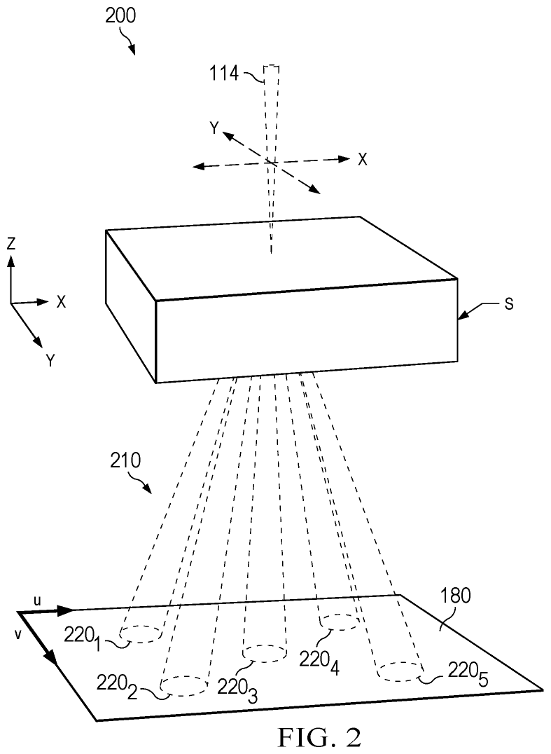

FIG. 2 is a block diagram illustrating acquisition of a diffraction pattern 210 using a portion 200 of the scientific instrument 100 in accordance with some embodiments. The diffraction pattern 210 is formed when the electron beam 114 impinging onto a crystalline sample S is diffracted thereby to form a plurality of diffraction spots 220; on the electron detector 180 appropriately positioned under the sample S. e.g., as indicated in FIG. 2. For illustration purposes and without any implied limitations, five such diffraction spots, labeled 220₁-220₅, are shown in FIG. 2.

In some examples, the STEM column 102 and the electron detector 180 are operated to capture a plurality of 2D convergent beam electron diffraction (CBED) patterns 210, I(u, v), for multiple scan-pixel positions, (x, y), in the 2D STEM scan of the sample S, where I( ) denotes intensity. In some cases, the resulting acquired dataset is presented as a 4D dataset, I(u, v, x, y), and the corresponding diffraction-pattern acquisition method is referred to as 4D STEM. The size of the diffraction spots 220; in the CBED pattern 210 can be controlled by varying the convergence angle of the electron beam 114. The choices of the electron detector 180 and convergence angle of the electron beam 114 typically depend on the type of information that the user of the scientific instrument 100 wishes to extract from the 4D dataset.

Information about the strain in a probed region of the sample S is contained in the Bragg angles of the diffraction pattern 210 of that region. By scanning the electron beam 114 over the sample S and acquiring a corresponding diffraction pattern 210 at each scan-pixel position (x, y), the strain can be mapped with a spatial resolution that approximately corresponds to the transverse beam size at the sample S. In some configurations, a small (e.g., a few nm in diameter) collimated (e.g., nearly parallel) electron beam 114 is used to obtain diffraction patterns 210 with sharp Bragg diffraction spots 220ᵢ. In some other configurations, larger convergence angles (e.g., several milliradians) of the electron beam 114 can similarly be used to obtain diffraction patterns 210. For at least some samples S, the use of such larger convergence angles may be preferred for carrying out strain measurements.

In some configurations, the strain precision of 4D-STEM-based strain mapping can be enhanced by imposing precession on the electron beam 114. In such configurations, each of the resulting diffraction patterns 210 is an average of diffraction patterns corresponding to (slightly) different incident beam directions sampled via the precession. This type of averaging typically increases the number of diffraction spots 220; that can be recorded by the electron detector 180 and also averages out many different dynamical scattering conditions. The averaging can be particularly beneficial for strain mapping with larger convergence angles.

In some examples, the electron detector 180 is implemented using a pixelated CCD camera having phosphorescent scintillators paired with a charge coupled device (CCD). In some other examples, the electron detector 180 is implemented using a monolithic active pixel sensor (MAPS) or a hybrid pixel detector (HPD). In yet some other examples, the electron detector 180 is implemented using a hybrid pixel array detector (PAD). The number of pixels in these types of detectors is typically in the range from about 10⁴ (e.g., 100×100 pixels) to about 10⁷ (e.g., 4000×4000 pixels). The corresponding acquisition time (e.g., including beam-dwell time and frame-readout time) is typically in the range between about 0.1 ms and about 10 ms per frame. In some cases, the corresponding acquisition time is greater than 10 ms per frame. However, for at least some (e.g., high-resolution) strain-mapping applications, in which a very large number of diffraction patterns 210 (frames) needs to be acquired, such acquisition times may not support fast and accurate strain mapping desired, e.g., in an industrial setting. For example, semiconductor companies typically target strain mapping with approximately 1 nm spatial resolution and approximately 0.01% to 0.1% strain precision coupled with fast data acquisition and processing.

These and possibly some related problems in the state of the art can beneficially be addressed using various embodiments disclosed herein. For example, one embodiment provides a segmented electron detector 180 capable of adequately capturing a frame with an individual diffraction pattern 210 in as little as approximately 25 ns, which represents an approximately three orders of magnitude reduction in the acquisition time per frame for strain-mapping applications with respect to that achievable with some conventional 4D STEM detectors. In some examples, the short acquisition time supported by the disclosed segmented electron detectors 180 can beneficially be leveraged to implement strain imaging (as opposed to strain mapping) in real time.

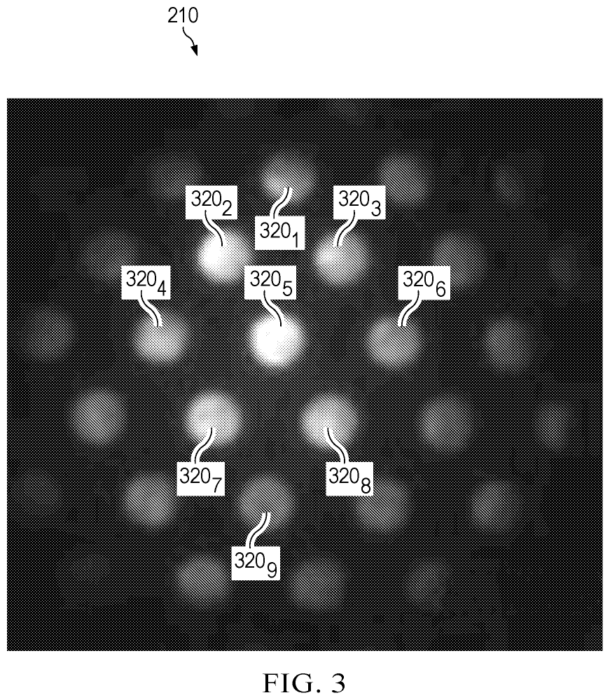

FIG. 3 shows the diffraction pattern 210 projected onto the electron detector 180 according to one example. In the example shown, the diffraction pattern 210 pattern corresponds to the sample S comprising crystalline silicon. The diffraction pattern 210 includes a plurality of diffraction spots 320ᵢ, only some of which are labeled using the reference numerals 320₁-320₉ to facilitate the description of example embodiments below.

For most use cases, a material of the sample S under test is known, and only deviations from the reference (e.g., strain-free) lattice geometry of that material need to be ascertained. As such, in various examples, experimental strain mapping includes measuring distances between a selected subset of the diffraction spots 320; and comparing the measured distances with the corresponding reference distances. The subset of the diffraction spots 320; used for strain-mapping purposes may be selected based on (i) relative intensity of the spots (e.g., only relatively bright spots 320; are selected) and (ii) sufficiency of the selected subset of diffraction spots for the extraction of desired strain information for the sample S. For many types of samples S, only the vectorial differences between a relatively small number (e.g., <10) of the diffraction spots 320; are needed to quantify the strain in the material. In some examples, at least three non-colinear diffraction spots 320; are included in the selected subset to quantify the strain in two dimensions.

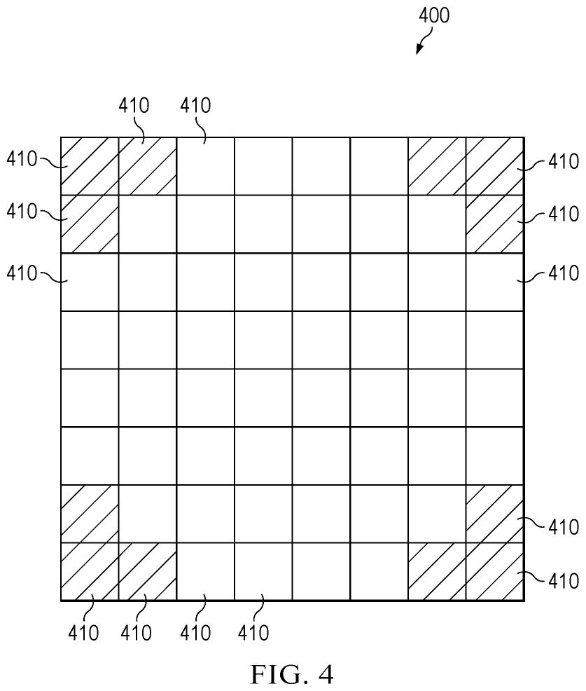

FIG. 4 is a block diagram illustrating a layout 400 of the segmented electron detector 180 according to an embodiment. The layout 400 includes sixty-four rectangular or square segments 410 arranged in eight rows and eight columns. In operation, each segment 410 integrates the respective flux of electrons impinging thereupon over the dwell time and outputs a single intensity value representing the integrated flux. Accordingly, each frame captured by the segmented electron detector 180 having the layout 400 is represented by sixty-four intensity values Iᵢ, which can be read out in a very short amount of time, thereby enabling the segmented electron detector 180 to be reset quickly for capturing a next frame.

In some embodiments, a modified layout 400 does not have the hashed segments 410 and, as such, includes a total of fifty-two segments 410. The modified layout 400 represents a detector-design example according to which square or rectangular segments 410 are used to form the segmented electron detector 180 having an overall geometric shape that is neither square nor rectangular. In different embodiments, different numbers and/or tiled arrangements of square or rectangular segments 410 can be used to construct segmented electron detectors 180 having different closed rectilinear shapes.

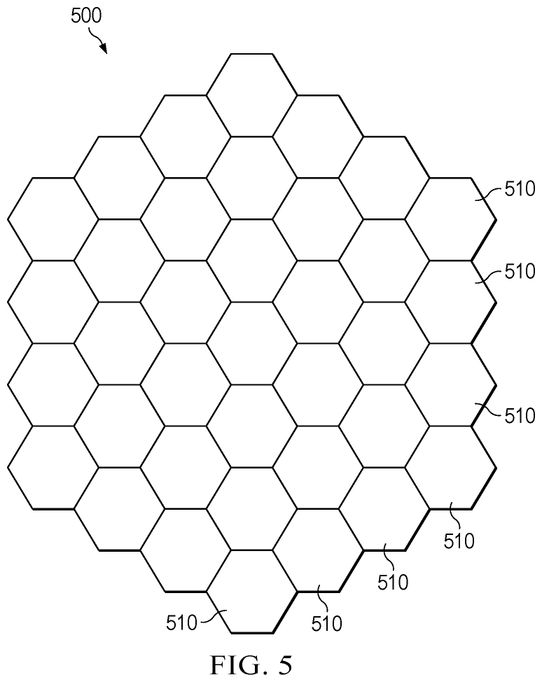

FIG. 5 is a block diagram illustrating a layout 500 of the segmented electron detector 180 according to another embodiment. The layout 500 includes thirty-seven hexagonal segments 510 arranged in a honeycomb pattern. Operation of the segments 510 is generally similar to the above-indicated operation of the segments 410. Each frame captured by the segmented electron detector 180 having the layout 500 is represented by thirty-seven intensity values Iᵢ.

In various additional embodiments, other suitable layouts can also be used to implement the segmented electron detector 180. In some examples, the total number of segments in the segmented electron detector 180 is in the range between eight and one hundred (the range including the end values thereof) and, preferably, is greater than forty-seven. In some examples, the size and/or shape of individual segments in the same segmented electron detector 180 may vary. In some examples, the sizes and shapes of the segments in the segmented electron detector 180 are selected such that an individual diffraction spot 320; is fully captured by a corresponding local group of adjacent segments (e.g., 410 or 510) including at least two segments and, more preferably, at least three segments.

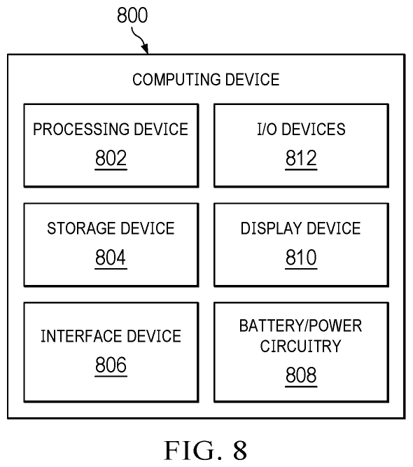

In some examples, a frame captured by the segmented electron detector 180 is processed using the electronic controller 150 or a computing device (e.g., 800, FIG. 8) communicatively coupled to the electronic controller 150 to determine spot positions in the diffraction pattern 210 using a center of mass (COM) approach. A mathematical framework of the COM approach can be represented using the following set of equations:

$$I = {\sum }_{i ∈ D} {I}_{i} \qquad ( 1 )$$

$${COM}_{u} = \frac{1}{I} {\sum }_{i ∈ D} {I}_{i} {u}_{i} \qquad ( 2 )$$

$${COM}_{v} = \frac{1}{I} {\sum }_{i ∈ D} {I}_{i} {v}_{i} \qquad ( 3 )$$

where D is the subset of segments receiving the flux of electrons representing an individual diffraction spot 320ₙ; Iᵢ is the intensity value registered by the i-th segment; uᵢ and vᵢ are the x and y coordinates (in reciprocal space) of the geometric center of the i-th segment in the segmented electron detector 180; COMᵤ and COMᵥ are the u and v coordinates (in reciprocal space) of the center of mass of the individual diffraction spot 320ₙ captured by the subset D. Using Eqs. (1)-(3), the respective center of mass coordinates (COMᵥ, COMᵥ)ₙ of each selected individual diffraction spot 320ₙ can be computed based on the corresponding frame {Iᵢ} captured by the segmented electron detector 180. In some examples, the individual diffraction spots 320ₙ can be indexed using the corresponding Miller indices.

For illustration purposes and without any implied limitations, example embodiments are described herein in reference to the above-described COM algorithm. However, various embodiments are not so limited. From the provided description, a person of ordinary skill in the pertinent art will readily understand how to adapt other suitable algorithms to appropriately process the frame captured by the segmented electron detector 180.

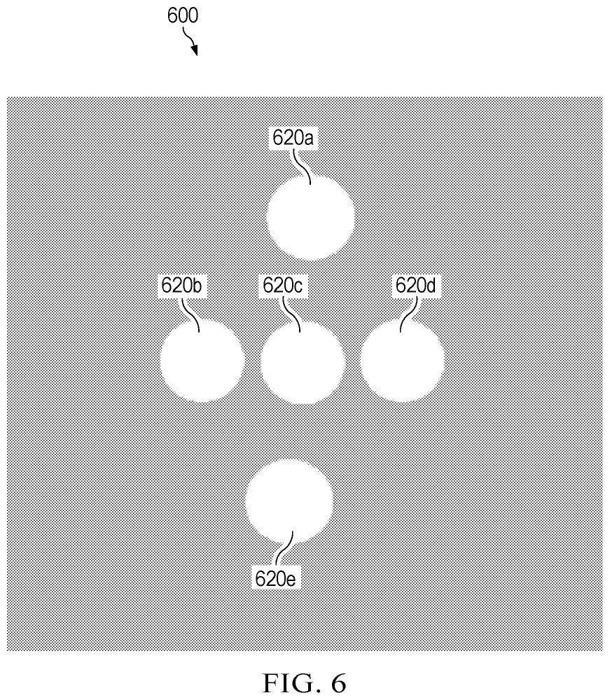

FIG. 6 is a block diagram illustrating a diffraction mask 600 that can be used with the segmented electron detector 180 according to one embodiment. In the example shown, the diffraction mask is electrically conducting and has five openings therein, labeled 620a-620e. In an example configuration, the mask is overlayed on the segmented electron detector 180 on the side thereof facing the sample S (also see FIG. 2) and is electrically connected to an electron sink (e.g., a ground terminal). In this configuration, any electrons that impinge on the body of the mask 600 are sunk away, and only the electrons that pass through the openings 620a-620e reach the segmented electron detector 180 and are detected thereby.

In the example shown, the openings 620a-620e are positioned and shaped such that only the diffracted electron beams corresponding to the diffraction spots 320₁, 320₄, 320₅, 320₆, and 320₉ can reach the underlying segments of the segmented electron detector 180 (also see FIG. 3). The diffracted electron beams corresponding to all other diffraction spots hit the body of the mask 600 and, as such, are sunk away before they can reach the segmented electron detector 180. In some examples, the openings 620a-620e are circular in shape and have respective diameters that are larger than the diameters of the corresponding diffracted electron beams intended to pass there through. The diameter ratio of the diffracted beam and the corresponding one of the openings 620a-620e can be selected such that the diffracted-beam angle variations caused by the anticipated range of strains in the sample S are accommodated by that opening without inflicting any cropping of the diffracted beam for at least some strain values. In some examples, at least some of the openings 620a-620e may have oblong or elliptical shapes, with the long axis of the opening being aligned with the direction along which the corresponding diffraction spot is expected to shift when the strain in the sample S changes.

In at least some embodiments, the segmented electron detector 180 is provided with a plurality of differently shaped, changeable diffraction masks that are functionally similar to the diffraction mask 600. Different ones of such masks have different respective patterns of openings that may be optimized for different diffraction patterns 210 expected for different respective sample materials and/or sample orientations. According to some embodiments, the use of a diffraction mask with the segmented electron detector 180 is optional. However, the use of a diffraction mask (such as the diffraction mask 600) is recommended in cases where the diffraction pattern 210 and the layout of the segments of the segmented electron detector 180 are such that there are one or more instances in which two (or more) different diffraction spots (e.g., 220ᵢ) of the diffraction pattern 210 contribute to the electron flux detected by a corresponding same one segment of the segmented electron detector 180. Such instances are eliminated by sinking some of the diffracted electron beams into the mask having a pattern of openings configured such that each of the underlying segments of the segmented electron detector 180 can only receive an electron flux from no more than a single diffracted beam. Due to such disambiguation of the received electron fluxes achieved with the diffraction mask, a better accuracy in the determination of the COM coordinates (COMᵤ, COMᵥ)ₙ can typically be achieved in at least some cases (also see Eqs. (1)-(3)).

In various examples, to achieve the above-mentioned disambiguation of the received electron fluxes, the diffraction mask 600 is properly aligned with the corresponding diffraction pattern. The mask alignment can be performed in different ways including, but not limited to: (1) loading the sample S in a well-defined and controlled way such that the diffraction pattern and the diffraction mask 600 are aligned due to such loading; (2) rotating the sample S about the Z-axis using a suitable sample manipulator connected to or integrated with the sample holder 110 until the diffraction pattern and the diffraction mask 600 become aligned; and (3) electronically rotating the diffraction pattern with respect to the diffraction mask 600, e.g., as described in U.S. Pat. No. 10,224,174, which is incorporated herein by reference in its entirety.

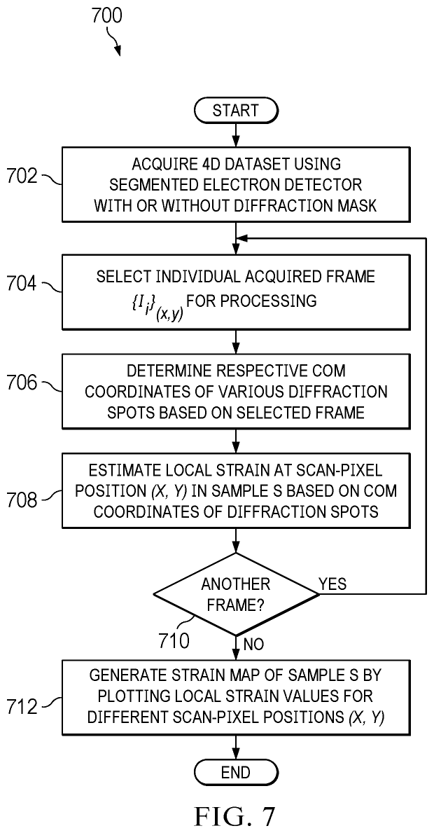

FIG. 7 is a flowchart illustrating a strain-mapping method 700 implemented in the scientific instrument 100 according to some embodiments. The method 700 uses a suitable embodiment of the above-described segmented electron detector 180, with or without a diffraction mask. Various operations of the method 700 are performed using the electronic controller 150, e.g., as described in more detail below.

The method 700 includes the electronic controller 150 operating various pertinent components of the scientific instrument 100 to acquire, with the segmented electron detector 180, a 4D dataset corresponding to the sample S (in a block 702). In a representative example, the 4D dataset includes a plurality of detected frames {Iᵢ}_{(x,y)}, with each of the detected frames corresponding to a different respective scan-pixel position (x, y) (also see FIGS. 1-2). The frames {Iᵢ}_{(x,y)} are sequentially read out from the segmented electron detector 180 when the corresponding exposure of the respective scan pixel to the electron beam 114 is completed. The read-out segment intensity values Iᵢ are then stored in a suitable frame format in a memory accessible to the electronic controller 150.

The method 700 also includes the electronic controller 150 accessing the memory (in a block 704) to select an individual frame {Iᵢ}_{(x,y)} for further processing. In various examples, different individual frames {Iᵢ}_{(x,y)} can be selected, in different respective instances of the block 704, in any suitable order until all pertinent frames of the 4D dataset acquired in the block 702 have been selected and processed.

The method 700 also includes the electronic controller 150 processing (in a block 706) the intensity values Iᵢ of the individual frame {Iᵢ}(x,y) selected in the block 704 to determine the respective COM coordinates of various pertinent diffraction spots (e.g., 220ᵢ) of the diffraction pattern 210 captured in the frame. In some examples, the electronic controller 150 operates to determine such COM coordinates based on Eqs. (1)-(3). In some examples, the determination of the respective COM coordinates is made using a frame obtained by averaging two or more individual frames {Iᵢ}_{(x,y)}.

The method 700 also includes the electronic controller 150 estimating (in a block 708) a local strain at the scan-pixel position (x, y) in the sample S based on the COM coordinates determined in the preceding block 706. In some examples, operations of the block 708 include fitting a strain model of the material in question to the set of COM coordinates determined in the block 706 to obtain a model-predicted strain value corresponding to the model's best fit. The model-predicted strain value is then used as an estimate of the local strain in the sample S at the scan-pixel position (x, y).

Operations of a decision block 710 of the method 700 include the electronic controller 150 determining whether or not all pertinent individual frames {Iᵢ}_{(x,y)} of the 4D dataset acquired in the block 702 have been processed. When it is determined that at least one of the individual frames {Iᵢ}_{(x,y)} still needs to be processed (“Yes” at the decision block 710), the method 700 is looped back to the operations of the block 704. When it is determined that all individual frames {Iᵢ}_{(x,y)} have been processed (“No” at the decision block 710), the method 700 is advanced to operations of a block 712.

Operations of the block 712 of the method 700 include the electronic controller 150 generating a strain map of the sample S, e.g., by plotting the local strain values determined in various instances of the block 708 as a function of the scan-pixel positions (x, y). In some examples of the block 712, the local strain values are color-coded, and the strain map is displayed, as a pixelated color image, on a display device connected to the electronic controller 150. In some examples, the displayed strain map shows one or more (but not all) directional components of the strain field. Upon completion of the operations of the block 712, the method 700 is terminated.

FIG. 8 is a block diagram of an example computing device 800 configured to perform at least some scientific-instrument support operations in accordance with various embodiments. For example, in some embodiments, the computing device 800 performs at least some operations of the electronic controller 150 (also see FIG. 1). In various embodiments, a support module of the scientific instrument 100 may be implemented by a single computing device 800 or by multiple computing devices 800.

The computing device 800 of FIG. 8 is illustrated as having a number of components, but any one or more of these components may be omitted or duplicated, as suitable for the application and setting. In some embodiments, some or all of the components included in the computing device 800 may be attached to one or more motherboards and enclosed in a housing. In some embodiments, some of those components may be fabricated onto a single system-on-a-chip (SoC) (e.g., the SoC may include one or more processing devices 802 and one or more storage devices 804). Additionally, in various embodiments, the computing device 800 may not include one or more of the components illustrated in FIG. 8, but may include interface circuitry for coupling to the one or more components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 800 may not include a display device 810, but may include display device interface circuitry (e.g., a connector and driver circuitry) to which an external display device 810 may be coupled.

The computing device 800 includes a processing device 802 (e.g., one or more processing devices). As used herein, the term “processing device” refers to any device or portion of a device that processes electronic data from registers and/or memory to transform that electronic data into other electronic data that may be stored in registers and/or memory. In various embodiments, the processing device 802 may include one or more digital signal processors (DSPs), application-specific integrated circuits (ASICs), central processing units (CPUs), graphics processing units (GPUs), server processors, or any other suitable processing devices.

The computing device 800 also includes a storage device 804 (e.g., one or more storage devices). In various embodiments, the storage device 804 may include one or more memory devices, such as random-access memory (RAM) devices (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some embodiments, the storage device 804 may include memory that shares a die with the processing device 802. In such an embodiment, the memory may be used as cache memory and include embedded dynamic random-access memory (eDRAM) or spin transfer torque magnetic random-access memory (STT-MRAM), for example. In some embodiments, the storage device 804 may include non-transitory computer readable media having instructions thereon that, when executed by one or more processing devices (e.g., the processing device 802), cause the computing device 800 to perform any appropriate ones of the methods disclosed herein or portions of such methods.

The computing device 800 further includes an interface device 806 (e.g., one or more interface devices 806). In various embodiments, the interface device 806 may include one or more communication chips, connectors, and/or other hardware and software to govern communications between the computing device 800 and other computing devices. For example, the interface device 806 may include circuitry for managing wireless communications for the transfer of data to and from the computing device 800. The term “wireless” and its derivatives may be used to describe circuits, devices, systems, methods, techniques, communications channels, etc., that may communicate data via modulated electromagnetic radiation through a nonsolid medium. The term does not imply that the associated devices do not contain any wires, although in some embodiments they might not. Circuitry included in the interface device 806 for managing wireless communications may implement any of a number of wireless standards or protocols, including but not limited to Institute for Electrical and Electronic Engineers (IEEE) standards including Wi-Fi (IEEE 802.11 family), IEEE 802.16 standards, Long-Term Evolution (LTE) project along with any amendments, updates, and/or revisions (e.g., advanced LTE project, ultramobile broadband (UMB) project (also referred to as “3GPP2”), etc.). In some embodiments, circuitry included in the interface device 806 for managing wireless communications may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some embodiments, circuitry included in the interface device 806 for managing wireless communications may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some embodiments, circuitry included in the interface device 806 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some embodiments, the interface device 806 may include one or more antennas (e.g., one or more antenna arrays) configured to receive and/or transmit wireless signals.

In some embodiments, the interface device 806 may include circuitry for managing wired communications, such as electrical, optical, or any other suitable communication protocols. For example, the interface device 806 may include circuitry to support communications in accordance with Ethernet technologies. In some embodiments, the interface device 806 may support both wireless and wired communication, and/or may support multiple wired communication protocols and/or multiple wireless communication protocols. For example, a first set of circuitry of the interface device 806 may be dedicated to shorter-range wireless communications such as Wi-Fi or Bluetooth, and a second set of circuitry of the interface device 806 may be dedicated to longer-range wireless communications such as global positioning system (GPS), EDGE, GPRS, CDMA, WiMAX, LTE, EV-DO, or others. In some other embodiments, a first set of circuitry of the interface device 806 may be dedicated to wireless communications, and a second set of circuitry of the interface device 806 may be dedicated to wired communications.

The computing device 800 also includes battery/power circuitry 808. In various embodiments, the battery/power circuitry 808 may include one or more energy storage devices (e.g., batteries or capacitors) and/or circuitry for coupling components of the computing device 800 to an energy source separate from the computing device 800 (e.g., to AC line power).

The computing device 800 also includes a display device 810 (e.g., one or multiple individual display devices). In various embodiments, the display device 810 may include any visual indicators, such as a heads-up display, a computer monitor, a projector, a touchscreen display, a liquid crystal display (LCD), a light-emitting diode display, or a flat panel display.

The computing device 800 also includes additional input/output (I/O) devices 812. In various embodiments, the I/O devices 812 may include one or more data/signal transfer interfaces, audio I/O devices (e.g., microphones or microphone arrays, speakers, headsets, earbuds, alarms, etc.), audio codecs, video codecs, printers, sensors (e.g., thermocouples or other temperature sensors, humidity sensors, pressure sensors, vibration sensors, etc.), image capture devices (e.g., one or more cameras), human interface devices (e.g., keyboards, cursor control devices, such as a mouse, a stylus, a trackball, or a touchpad), etc.

Depending on the specific embodiment of the scientific instrument 100 and/or of the instrument portion 200, various components of the interface devices 806 and/or I/O devices 812 can be configured to output suitable control signals (e.g., 152, 154, 156) for various components of the scientific instrument 100, receive suitable control/telemetry signals from various components of the scientific instrument 100, and receive streams of measurements (e.g., 162, 172, 182) from various detectors of the scientific instrument 100. In some examples, the interface devices 806 and/or I/O devices 812 include one or more analog-to-digital converters (ADCs) for transforming received analog signals into a digital form suitable for operations performed by the processing device 802 and/or the storage device 804. In some additional examples, the interface devices 806 and/or I/O devices 812 include one or more digital-to-analog converters (DACs) for transforming digital signals provided by the processing device 802 and/or the storage device 804 into an analog form suitable for being communicated to the corresponding components of the scientific instrument 100.

According to one example disclosed above, e.g., in the summary section and/or in reference to any one or any combination of some or all of FIGS. 1-8, provided is an apparatus comprising: an electron-beam column configured to scan an electron beam across a sample; a segmented electron detector configured to receive a plurality of diffracted beams produced by diffraction of the electron beam in the sample, the segmented electron detector having a plurality of segments arranged in a two-dimensional array, with each of the segments being configured to generate a respective output signal representing a respective integrated flux of electrons received thereat; and an electronic controller configured to receive a set of frames from the segmented electron detector, each of the frames representing a respective set of output signals generated by the segments in response to an electron diffraction pattern projected onto the segmented electron detector from a respective position of the electron beam during a scan of the sample, wherein a total number of segments in the segmented electron detector is smaller than 1000; and wherein the electronic controller is configured to generate a strain map of the sample based on the set of frames.

In some examples of the above apparatus, the total number is smaller than 200 (or 500, or 100).

In some examples of any of the above apparatus, the total number is in a range from 8 to 100.

In some examples of any of the above apparatus, the segmented electron detector has a layout in which a substantially full flux of an individual one of the diffracted beams is captured by a respective contiguous group of segments having fewer than 10 (or 8, or 5) of the segments. As used herein, the term “substantially full flux” should be construed to mean more than 90% (or 95%, or 99%, or 99.9%, or 99.99%) of the total flux of a diffracted beam that forma a corresponding Bragg diffraction spot of the diffraction pattern 210.

In some examples of any of the above apparatus, the segmented electron detector has a layout in which a substantially full flux of an individual one of the diffracted beams is captured by a respective contiguous group of segments having more than one but fewer than eight of the segments.

In some examples of any of the above apparatus, the segments are hexagonal in shape and are arranged in the two-dimensional array to form a honeycomb pattern.

In some examples of any of the above apparatus, the segments are rectangular or square in shape and are arranged in the two-dimensional array to form a plurality of parallel rows.

In some examples of any of the above apparatus, the segments are arranged in a two-dimensional array to form an annular pattern.

In some examples of any of the above apparatus, the segmented electron detector includes a first segment having a first geometric shape and a second segment having a different second geometric shape.

In some examples of any of the above apparatus, the apparatus further comprises a diffraction mask positioned between the sample and the segmented electron detector to stop a subset of the diffracted beams from reaching the segmented electron detector.

In some examples of any of the above apparatus, the diffraction mask has a plurality of openings configured to cause any one segment of the segmented electron detector to receive electrons of no more than one of the diffracted beams.

In some examples of any of the above apparatus, the diffraction mask is changeable and is selectable from a plurality of differently shaped diffraction masks.

In some examples of any of the above apparatus, the electronic controller is configured to: determine COM coordinates for a set of diffraction spots of the electron diffraction pattern using a selected frame of the set of frames; estimate a local strain in the sample based on the COM coordinates of the set of diffraction spots; and generate the strain map of the sample based on values of the local strain estimated from different selected frames of the set of frames.

According to another example disclosed above, e.g., in the summary section and/or in reference to any one or any combination of some or all of FIGS. 1-8, provided is a strain mapping method comprising: acquiring a set of frames by operating an electron-beam column to scan an electron beam across a sample and further operating a segmented electron detector configured to receive a plurality of diffracted beams produced by diffraction of the electron beam in the sample, the segmented electron detector having a plurality of segments arranged in a two-dimensional array, each of the segments being configured to generate a respective output signal representing a respective integrated flux of electrons received thereby, each of the frames representing a respective set of output signals generated by the segments in response to an electron diffraction pattern projected onto the segmented electron detector from a respective position of the electron beam during a scan of the sample; and generating, with a processor, a strain map of the sample based on the set of frames, wherein a total number of segments in the segmented electron detector is smaller than 1000.

In some examples of the above method, the generating comprises: determining center-of-mass (COM) coordinates for a set of diffraction spots of the electron diffraction pattern using a selected frame of the set of frames; estimating a local strain in the sample based on the COM coordinates of the set of diffraction spots; and generating the strain map of the sample based on values of the local strain estimated from different selected frames of the set of frames.

In some examples of any of the above methods, the method further comprises placing a diffraction mask between the sample and the segmented electron detector to stop a subset of the diffracted beams from reaching the segmented electron detector.

In some examples of any of the above methods, the method further comprises selecting the diffraction mask from a plurality of differently shaped diffraction masks.

In some examples of any of the above methods, the selecting comprises selecting the diffraction mask having a plurality of openings configured to cause any one segment of the segmented electron detector to receive electrons of no more than one of the diffracted beams during the acquiring.

In some examples of any of the above methods, the selecting is based on a material of the sample.

In some examples of any of the above methods, the method further comprises: placing a first diffraction mask between the sample and the segmented electron detector for scanning a first area of the sample comprising a first crystalline material; and replacing the first diffraction mask by a different second diffraction mask for scanning a second area of the sample comprising a different second crystalline material.

It is to be understood that the above description is intended to be illustrative and not restrictive. Many implementations and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future examples. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary.

The Abstract is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that the claimed subject matter incorporate more features than are expressly recited in each claim. Rather, as the following claims reflect, inventive subject matter lies in fewer than all features of a single disclosed example. Thus, the following claims are hereby incorporated into the Detailed Description, with each claim standing on its own as a separately claimed subject matter.

Unless explicitly stated otherwise, each numerical value and range should be interpreted as being approximate as if the word “about” or “approximately” preceded the value or range.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Unless otherwise specified herein, the use of the ordinal adjectives “first,” “second,” “third,” etc., to refer to an object of a plurality of like objects merely indicates that different instances of such like objects are being referred to, and is not intended to imply that the like objects so referred-to have to be in a corresponding order or sequence, either temporally, spatially, in ranking, or in any other manner.

Unless otherwise specified herein, in addition to its plain meaning, the conjunction “if” may also or alternatively be construed to mean “when” or “upon” or “in response to determining” or “in response to detecting.” which construal may depend on the corresponding specific context. For example, the phrase “if it is determined” or “if [a stated condition] is detected” may be construed to mean “upon determining” or “in response to determining” or “upon detecting [the stated condition or event]” or “in response to detecting [the stated condition or event].”

Also for purposes of this description, the terms “couple,” “coupling.” “coupled.” “connect,” “connecting.” or “connected” refer to any manner known in the art or later developed in which energy is allowed to be transferred between two or more elements, and the interposition of one or more additional elements is contemplated, although not required. Conversely, the terms “directly coupled.” “directly connected.” etc., imply the absence of such additional elements.

The functions of the various elements shown in the figures, including any functional blocks labeled as “processors” and/or “controllers,” may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and nonvolatile storage. Other hardware, conventional and/or custom, may also be included. Similarly, any switches shown in the figures are conceptual only. Their function may be carried out through the operation of program logic, through dedicated logic, through the interaction of program control and dedicated logic, or even manually, the particular technique being selectable by the implementer as more specifically understood from the context.

As used in this application, the terms “circuit,” “circuitry” may refer to one or more or all of the following: (a) hardware-only circuit implementations (such as implementations in only analog and/or digital circuitry); (b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions); and (c) hardware circuit(s) and or processor(s), such as a microprocessor(s) or a portion of a microprocessor(s), that requires software (e.g., firmware) for operation, but the software may not be present when it is not needed for operation.” This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

It should be appreciated by those of ordinary skill in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

What is claimed is:

1. An apparatus, comprising:
an electron-beam column configured to scan an electron beam across a sample;
a segmented electron detector configured to receive a plurality of diffracted beams produced by diffraction of the electron beam in the sample, the segmented electron detector having a plurality of segments arranged in a two-dimensional array, with each of the segments being configured to generate a respective output signal representing a respective integrated flux of electrons received thereat; and
an electronic controller configured to receive a set of frames from the segmented electron detector, each of the frames representing a respective set of output signals generated by the segments in response to an electron diffraction pattern projected onto the segmented electron detector from a respective position of the electron beam during a scan of the sample and further configured to communicate with a computing device programmed to generate a strain map of the sample based on the set of frames,
wherein a total number of segments in the segmented electron detector is smaller than 1000.

2. The apparatus of claim 1, wherein the total number is smaller than 200.

3. The apparatus of claim 1, wherein the total number is in a range from 8 to 100.

4. The apparatus of claim 1, wherein the segmented electron detector has a layout in which a substantially full flux of an individual one of the diffracted beams is captured by a respective contiguous group of segments having fewer than ten of the segments.

5. The apparatus of claim 1, wherein the segmented electron detector has a layout in which a substantially full flux of an individual one of the diffracted beams is captured by a respective contiguous group of segments having more than one but fewer than eight of the segments.

6. The apparatus of claim 1, wherein the segments are hexagonal in shape and are arranged in the two-dimensional array to form a honeycomb pattern.

7. The apparatus of claim 1, wherein the segments are rectangular or square in shape and are arranged in the two-dimensional array to form a plurality of parallel rows.

8. The apparatus of claim 1, wherein the segmented electron detector includes a first segment having a first geometric shape and a second segment having a different second geometric shape.

9. The apparatus of claim 1, further comprising a diffraction mask positioned between the sample and the segmented electron detector to stop a subset of the diffracted beams from reaching the segmented electron detector.

10. The apparatus of claim 9, wherein the diffraction mask has a plurality of openings configured to cause any one segment of the segmented electron detector to receive electrons of no more than one of the diffracted beams.

11. The apparatus of claim 9, wherein the diffraction mask is changeable and is selectable from a plurality of differently shaped diffraction masks.

12. The apparatus of claim 1, wherein the computing device is configured to:
determine center-of-mass (COM) coordinates for a set of diffraction spots of the electron diffraction pattern using a selected frame of the set of frames;
estimate a local strain in the sample based on the COM coordinates of the set of diffraction spots; and
generate the strain map of the sample based on values of the local strain estimated from different selected frames of the set of frames.

13. A strain mapping method, comprising:
acquiring a set of frames by operating an electron-beam column to scan an electron beam across a sample and further operating a segmented electron detector configured to receive a plurality of diffracted beams produced by diffraction of the electron beam in the sample, the segmented electron detector having a plurality of segments arranged in a two-dimensional array, each of the segments being configured to generate a respective output signal representing a respective integrated flux of electrons received thereby, each of the frames representing a respective set of output signals generated by the segments in response to an electron diffraction pattern projected onto the segmented electron detector from a respective position of the electron beam during a scan of the sample; and
generating, with a processor, a strain map of the sample based on the set of frames,
wherein a total number of segments in the segmented electron detector is smaller than 1000.

14. The strain mapping method of claim 13, wherein the generating comprises:
determining center-of-mass (COM) coordinates for a set of diffraction spots of the electron diffraction pattern using a selected frame of the set of frames;
estimating a local strain in the sample based on the COM coordinates of the set of diffraction spots; and
generating the strain map of the sample based on values of the local strain estimated from different selected frames of the set of frames.

15. The strain mapping method of claim 13, further comprising placing a diffraction mask between the sample and the segmented electron detector to stop a subset of the diffracted beams from reaching the segmented electron detector.

16. The strain mapping method of claim 15, further comprising selecting the diffraction mask from a plurality of differently shaped diffraction masks.

17. The strain mapping method of claim 16, wherein the selecting comprises selecting the diffraction mask having a plurality of openings configured to cause any one segment of the segmented electron detector to receive electrons of no more than one of the diffracted beams during the acquiring.

18. The strain mapping method of claim 16, wherein the selecting is based on a material of the sample.

19. The strain mapping method of claim 13, further comprising:
placing a first diffraction mask between the sample and the segmented electron detector for scanning a first area of the sample comprising a first crystalline material; and
replacing the first diffraction mask by a different second diffraction mask for scanning a second area of the sample comprising a different second crystalline material.

20. The strain mapping method of claim 13, wherein the total number is in a range from 8 to 100.
